(19) United States
(12) Patent Application Publication
(10) Pub. No.: US 2002/0158679 A1
(43) Pub. Date: Oct. 31, 2002

(54) Voltage control circuit

(76) Inventor: Takaaki Matsuo, Chiba-shi (JP)

Correspondence Address: ADAMS & WILKS, 31st Floor, 50 Broadway, New York, NY, 10004, US

(21) Appl. No.: 10/108,541

(22) Filed: Mar. 27, 2002

(30) Foreign Application Priority Data
Apr. 19, 2001 (JP) 2001-121337

(51) Int. Cl. H03L 5/00

(52) U.S. Cl. 327/309

(57) ABSTRACT

In an output short-circuiting protecting circuit, a current flows in advance in a current sense resistor that is connected to a current source circuit and monitors the current. When a desired short-circuiting current flows, a voltage for operating the protecting circuit is developed in the current sense resistor, and the current is adjusted to an arbitrary short-circuiting current.

### BACKGROUND OF THE INVENTION

1. Field of the Invention

The present invention relates to a voltage control circuit in a monolithic integrated circuit form, in particular, to an output voltage protecting circuit.

2. Description of the Related Art

There has been known an output short-circuiting protecting circuit for a voltage control circuit disclosed in Japanese Patent Examined Publication No. Hei 7-74976. A circuit diagram of the output short-circuiting protecting circuit for the conventional voltage control circuit is shown in FIG. 2. A voltage Vin inputted from an input terminal 201 is outputted to an output terminal 203 through a control MOS transistor 202. The output terminal 203 is connected with resistors 204 and 205, and a voltage at a node between the resistors 204 and 205 is inputted to a positive input terminal side of an amplifier 206. On the other hand, a negative input terminal side of the amplifier 206 is inputted with a reference voltage Vref from the power supply 207. Also, an output terminal of the amplifier 206 is connected to a gate of the control transistor 202.

A circuit in which a transistor 213 for monitoring a current and a resistor 208 are connected in series is inserted in parallel with the control transistor 202, and a gate voltage of the transistor 209 is supplied from a node of the transistor 213 and the resistor 208. A resistor 210 is inserted between the transistor 209 and the input terminal 201 to constitute an inverter circuit. The output voltage of the node 212 of the inverter circuit is inputted to a transistor 211 inserted between the gate and source of the control transistor 202. Also, the gate voltage of the transistor 213 is supplied from an amplifier 206 as in the control transistor 202.

An output current that can be extracted from the output terminal 203 by employing the above-described circuit structure and an output voltage characteristic at that time exhibit the characteristic shown in FIG. 5. In this example, Is is an output retaining current, Im is a maximum current.

However, the conventional output short-circuiting protecting circuit suffers from such a defect that it is difficult to adjust the output retaining current Is to an arbitrary value. This is because a resistance, a threshold value of the transistor, etc., vary from values estimated at the time of designing due to a variation of the manufacture process, a variation of the substrate density, a variation of characteristics of an element on a substrate, etc.

### SUMMARY OF THE INVENTION

An object of the present invention is to eliminate the drawbacks with the conventional device.

In the present invention, a current source circuit is newly added to allow a current to flow in advance in a current sense resistor that monitors the current. Then, when a desired short-circuiting current flows in the current sense resistor, a voltage for operating the protecting circuit develops in the current sense resistor to adjust the short-circuiting current to an arbitrary short-circuiting current.

The present invention uses a circuit in which a resistor is disposed in a current path, and a voltage drop developed by the resistor is detected to conduct a current limit. In this example, a back gate of an MOS transistor is used.

Further, there is used a voltage control circuit comprised of: a current monitor circuit connected in series to a transistor and a resistor; an output voltage control circuit that connects the current monitor circuit to an input terminal and an output terminal in parallel; and a current source circuit connected to the resistor. Still further, there is used a voltage control circuit comprised of: a current monitor circuit connected in series to a transistor and a resistor; an output voltage control circuit that connects the current monitor circuit to an input terminal and an output terminal in parallel; an output short-circuiting protecting circuit of the output voltage control circuit; and a current source circuit connected to the resistor, in which the current source circuit applies a voltage for operating the output short-circuiting protecting circuit to the resistor.

### BRIEF DESCRIPTION OF THE DRAWINGS

These and other objects and advantages of this invention will become more fully apparent from the following detailed description taken with the accompanying drawings in which:

FIG. 1 is a circuit diagram showing a first embodiment of the present invention;

FIG. 2 is a conventional voltage control circuit;

FIG. 3 is a circuit block diagram showing a measuring device in accordance with a second embodiment of the present invention;

FIG. 4 is a circuit block diagram showing a measuring device in accordance with a third embodiment of the present invention; and

FIG. 5 is an output voltage characteristic of a conventional voltage control circuit.

### DETAILED DESCRIPTION OF THE PREFERRED EMBODIMENTS

Now, a description will be given of preferred embodiments of the present invention with reference to the accompanying drawings.

(First Embodiment)

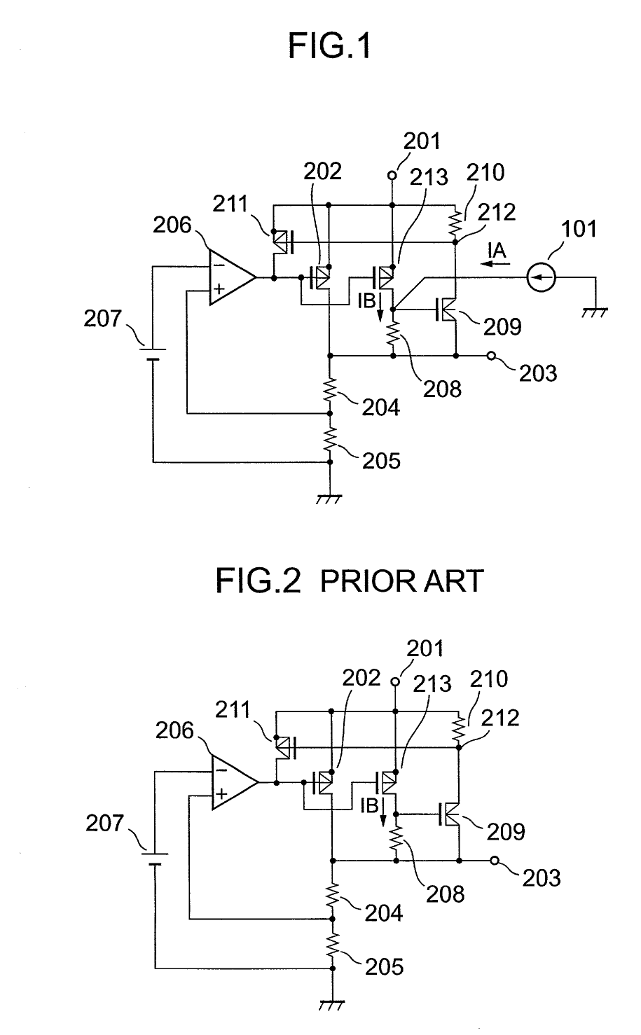

FIG. 1 is a circuit diagram showing a first embodiment of the present invention. The same parts as those in FIG. 2 will be omitted from their description. A current source 101 is connected to a node of a transistor 213 and a resistor 208. The current source 101 has a function of adjusting a current value by a design constant, a fuse trimming, a laser trimming or other methods.

When the output terminal 3 is short-circuited to a ground potential, a retaining current Is flows. The Is can be obtained by the following expression.

Is=N×(V_{TN}/R1−I_{A}) (1)

where V_{TN} is a threshold voltage of the transistor 209, R1 is a resistance of the resistor 208, N is a current mirror ratio of the transistor 202 and the transistor 213, and I_{A} is a current that flows in a node of the transistor 213 and the resistor 208 from the current source 101 or flows out of the node.

As is apparent from the expression (1), Is can be set to an arbitrary value by adjusting I_{A}. For example, in the case where Is is set to 30 mA, assuming that V_{TN}=0.5 V, R1=500 Ω, and the mirror ratio of the transistor 202 and the transistor 213 is 100,

30×0.001=100×(0.5/500−I_{A}) (2)

From the expression (2),

I_{A}=0.0007 A=0.7 mA

Therefore, when a current of 0.7 mA flows from the current source 101, the retaining current Is can be adjusted to 30 mA.

(Second Embodiment)

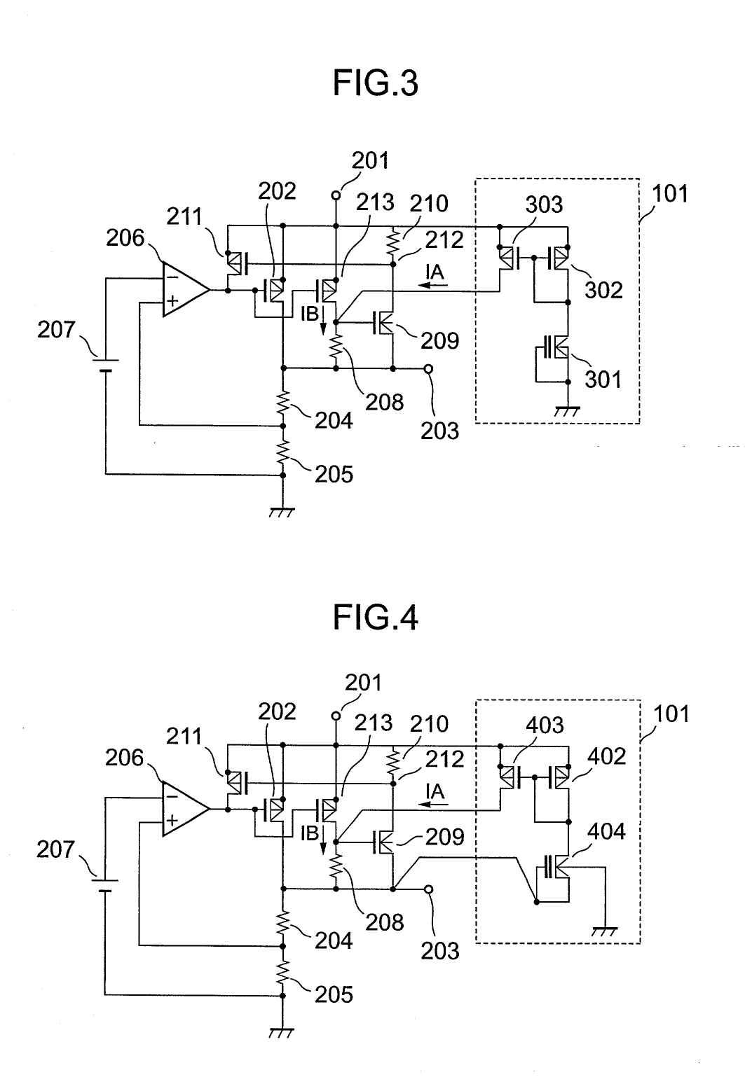

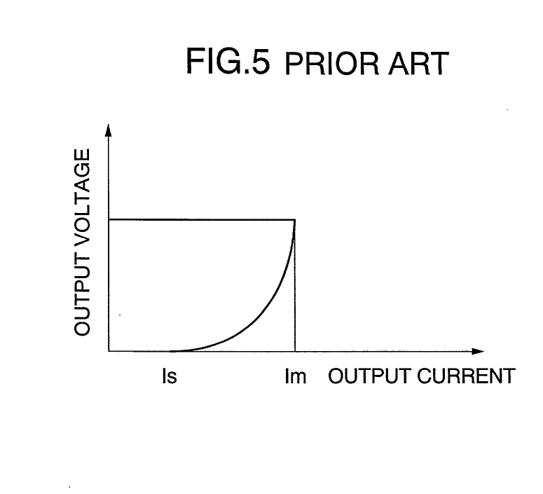

FIG. 3 is a circuit diagram showing a second embodiment of the present invention. Duplex portions of FIG. 1 will be omitted from description. A gate and source of a depletion type transistor 301 are grounded. A transistor 302 has a source and a bulk connected to an input terminal 201 and a gate and a drain connected to the transistor 301. A transistor 303 is connected to a node of the input terminal 201, a transistor 213 and a resistor 208. When a voltage is inputted to the input terminal and the drain voltage of the transistor 301 becomes a voltage of a threshold value or more, the transistor 301 functions as a constant current circuit. Since the transistor 302 and the transistor 301 have a common path along which the current flows, the equal current flows in the transistors 302 and 301. Because the transistor 302 and the transistor 303 have a common gate, a current I_{A} proportional to a current that flows in the transistor 301 flows in the transistors 302 and 303. The proportion constant of the current is determined by the respective sizes of the transistors 302 and 303. Assuming that the channel lengths of the transistors 302 and 303 are L1 and L2, respectively, the channel widths thereof are W1 and W2, respectively, and a current that flows in the depletion type transistor 301 is Idep, I_{A} is represented by the following expression.

I_{A}=(W2/L2)/(W1/L2)×Idep

Therefore, I_{A} can be adjusted by appropriately setting the sizes of the transistors 302 and 303. As described in the above first embodiment, the retaining current Is can be set to an arbitrary value by adjusting I_{A}, and it is apparent that Is can be adjusted to an arbitrary value in the circuit shown in FIG. 3.

(Third Embodiment)

FIG. 4 is a circuit diagram showing a third embodiment of the present invention. The duplex portions of FIGS. 1 to 3 will be omitted from description. A depletion type transistor 404 has a gate and a source connected to an output terminal 203, and a bulk grounded. A transistor 402 has a source and a bulk connected to an input terminal 201 and a gate and a drain connected to a transistor 404. A transistor 403 is connected to a node of the input terminal 201, a transistor 213 and a resistor 208. When a voltage is inputted to the input terminal and the drain voltage of the transistor 404 becomes a voltage of a threshold value or more, the transistor 404 functions as a constant current circuit. Since the transistor 402 and the transistor 404 have a common path along which the current flows, the equal current flows in the transistors 402 and 404. Because the transistor 402 and the transistor 403 have a common gate, a current I_{A} proportional to a current that flows in the transistor 404 flows in the transistors 402 and 403. The proportion constant of the current is determined by there spective sizes of the transistors 402 and 403. Assuming that the channel lengths of the transistors 402 and 403 are L1 and L2, respectively, the channel widths thereof are W1 and W2, respectively, and a current that flows in the depletion type transistor 404 is Idep, I_{A} is represented by the following expression.

I_{A}=(W2/L2)/(W1/L2)×Idep

Therefore, I_{A} can be adjusted by appropriately setting the sizes of the transistors 402 and 403. As described in the above first embodiment, the retaining current Is can be set to an arbitrary value by adjusting I_{A,} and it is apparent that Is can be adjusted to an arbitrary value in the circuit shown in FIG. 3.

As was described above, the measuring circuit according to the present invention has the following advantage. Since a current source is added to a conventional power source protecting circuit, and a current value from the current source is set to an appropriate value, a retaining current Is can be set to an arbitrary value.

The foregoing description of the preferred embodiments of the invention has been presented for purposes of illustration and description. It is not intended to be exhaustive or to limit the invention to the precise form disclosed, and modifications and variations are possible in light of the above teachings or may be acquired from practice of the invention. The embodiments were chosen and described in order to explain the principles of the invention and its practical application to enable one skilled in the art to utilize the invention in various embodiments and with various modifications as are suited to the particular use contemplated. It is intended that the scope of the invention be defined by the claims appended hereto, and their equivalents.

What is claimed is:

1. A voltage control circuit comprising:
a current monitor circuit connected in series to a transistor and a resistor;
an output voltage control circuit that connects said current monitor circuit to an input terminal and an output terminal in parallel; and
a current source circuit connected to said resistor.

2. A voltage control circuit comprising:
a current monitor circuit connected in series to a transistor and a resistor;
an output voltage control circuit that connects said current monitor circuit to an input terminal and an output terminal in parallel;
an output short-circuiting protecting circuit for said output voltage control circuit; and
a current source circuit connected to said resistor,
wherein said current source circuit applies a voltage for operating said output short-circuiting protecting circuit to said resistor.

3. A circuit in which a resistor is disposed in a current path, and a voltage drop developed by said resistor is detected to conduct a current limit.

4. A circuit in which a back gate of an MOS transistor is used among the circuits as claimed in claim 1.
